(19) United States
(12) Patent Application Publication
(10) Pub. No.: US 2020/0187352 A1
(43) Pub. Date: Jun. 11, 2020

(54) PRINTED CIRCUIT BOARD USING TWO-VIA GEOMETRY

(71) Applicant: Intel Corporation, Santa Clara, CA (US)

(72) Inventors: Wei Jern Tan, Georgetown (MY); Tony Lewis, Hillsboro, OR (US)

(21) Appl. No.: 16/662,717

(22) Filed: Oct. 24, 2019

(30) Foreign Application Priority Data
Dec. 7, 2018 (MY) PI 2018002434

(51) Int. Cl. H05K 1/11; H05K 1/02

(52) U.S. Cl. CPC H05K 1/115; H05K 1/0245; H05K 2201/10189; H05K 2201/09627; H05K 2201/09809; H05K 1/0243

(57) ABSTRACT

To reduce the effect of undesirable electrical resonances in via stubs (e.g., portions of electrically conductive material in a via that form an open circuit by electrically connecting at only one end), a multi-layer printed circuit board can electrically connect traces in different layers using two vias that are electrically connected to each other. For example, a first electrical trace can electrically connect to a first via at a first layer, the first via can electrically connect to a second via at the topmost layer (or the bottommost layer), and the second via can electrically connect to a second electrical trace at a second layer. Compared to a typical single-via connection scheme, the two-via connection scheme can produce stubs that are shorter in length and therefore have an increased resonant frequency that may avoid interference with electrical signals sent through the first and second electrical traces.

### PRIORITY

This patent application claims the benefit of priority to Malaysia Application Serial No. PI 2018002434, filed Dec. 7, 2018, which is incorporated by reference herein in its entirety.

### FIELD OF THE DISCLOSURE

The present disclosure relates generally to electrical routing in a printed circuit board.

### BACKGROUND OF THE DISCLOSURE

As bus interfaces, such as PCI Express (Peripheral Component Interconnect Express) and USB (Universal Serial Bus), increase in data rates, electrical artifacts from via architecture become increasingly important.

### BRIEF DESCRIPTION OF THE DRAWINGS

FIG. 1 shows a cross-sectional side view of an example of a printed circuit board (PCB), in accordance with some embodiments.

FIG. 2 shows a perspective view of an example of various electrically conductive elements of a printed circuit board (PCB), in accordance with some embodiments.

FIG. 3 shows a top-view schematic view of the electrical traces and vias of a printed circuit board, in accordance with some embodiments.

FIG. 4 illustrates a system level diagram, depicting an example of an electronic device (e.g., system) including the printed circuit board as described in the present disclosure.

FIG. 5 shows a flowchart of an example of a method for forming an electrical connection in a printed circuit board, in accordance with some embodiments.

FIG. 6 shows a plot of simulated insertion loss as a function of frequency, for plated through hole vias that lack a stub and include a stub.

FIG. 7 shows a plot of simulated time domain reflection, as a function of time, for plated through hole vias that lack a stub and include a stub.

FIG. 8 shows a plot of simulated insertion loss as a function of frequency, for plated through hole vias that lack a stub and include the two-via geometry discussed herein.

FIG. 9 shows a plot of simulated time domain reflection, as a function of time, for plated through hole vias that lack a stub and include the two-via geometry discussed herein.

Corresponding reference characters indicate corresponding parts throughout the several views. Elements in the drawings are not necessarily drawn to scale. The configurations shown in the drawings are merely examples, and should not be construed as limiting the scope of the inventive subject matter in any manner.

### DETAILED DESCRIPTION

In a typical multi-layer printed circuit board, a through-hole via can electrically connect a first electrical trace in a first layer to a second electrical trace in a second layer, below the first layer. If the first layer is not the topmost layer in the printed circuit board, then a top portion of the conductive material in the via, known as a stub and extending from the first layer to the topmost layer, can be electrically unconnected at its upper end and can form an open circuit that supports undesirable electrical resonances between the first layer and the topmost layer. Similarly, if the second layer is not the bottommost layer in the printed circuit board, then a bottom portion of the conductive material in the via, also known as a stub and extending from the second layer to the bottommost layer, can be electrically unconnected at its bottom end and can form an open circuit that supports undesirable electrical resonances between the second layer and the bottommost layer.

To reduce the effect of undesirable electrical resonances in the stubs, an improved multi-layer printed circuit board can instead electrically connect the first electrical trace to the second electrical trace using two vias that are electrically connected to each other, such as at a top layer or a bottom layer. For example, the first electrical trace can electrically connect to a first via at the first layer, the first via can electrically connect to a second via, such as at the topmost layer or the bottommost layer, and the second via can electrically connect to the second electrical trace at the second layer. Current can flow from the first electrical trace, through a portion of the first via, through the connecting portion, such as at the topmost or bottommost layer, through a portion of the second via, and to the second electrical trace. Current can also flow in the opposite direction to the electrical path described above.

Forming the electrical connection with two vias in this manner can still form stubs, such as between the first layer and the topmost layer and between the second layer and the topmost layer if the vias are connected to each other at the bottommost layer, or between the first layer and the bottommost layer and between the second layer and the bottommost layer if the vias are connected to each other at the topmost layer. Compared to the typical single-via connection scheme described above, the two-via connection scheme can produce stubs that are shorter in length than the typical single-via connection scheme. Because the stubs are reduced in length, any undesirable electrical resonances that arise in the stubs can have an increased resonant frequency. In many cases, the resonant frequency can increase to a frequency region that does not significantly conflict with a data rate of electrical signals sent through the first and second electrical traces.

In the figures and the text that follows, the terms “top” and “bottom” are used to show orientations of particular features on particular elements, or relative orientations of one element to another element. The designations of top and bottom are used merely for convenience and clarity, and are not intended to represent absolute orientation or direction. For example, a “top” surface of an element remains a top surface regardless of an absolute orientation of the element, even if the element is inverted during storage or use. This document uses the common convention of a chip package being positioned on top of a motherboard, which establishes directions of up and down, and top and bottom, relative to this convention.

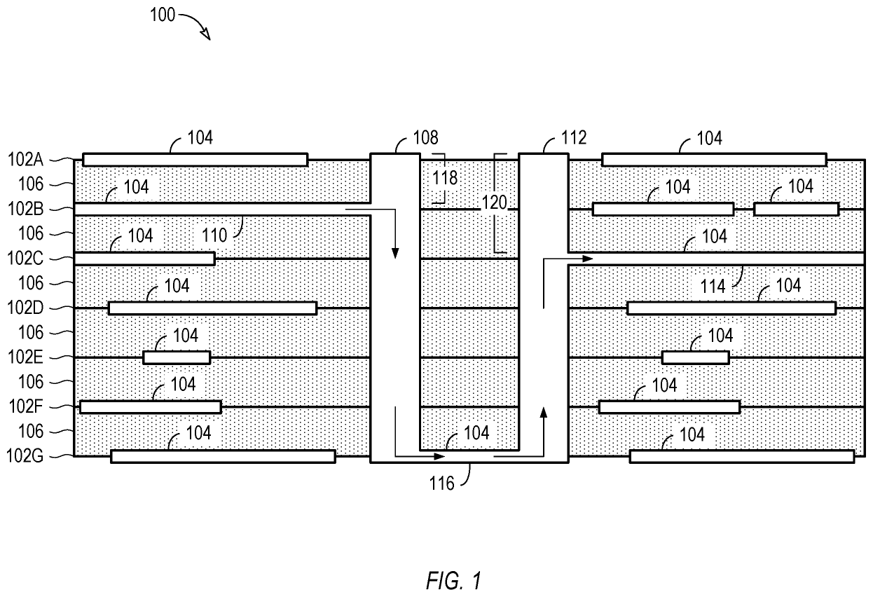

FIG. 1 shows a cross-sectional side view of an example of a printed circuit board (PCB) 100, in accordance with some embodiments. The printed circuit board 100 is but one example of a printed circuit board; other configurations can also be used.

A plurality of electrical trace layers 102A-G can extend parallel to one another. Each electrical trace layer 102A-G can be planar, or generally planar (allowing for slight curvature of insulating layers positioned between adjacent electrical trace layers 102A-G). Each electrical trace layer 102A-G can include one or more electrical traces 104 that can route current from one location to another within the electrical trace layer 102A-G. Each electrical trace 104 can be formed as a relatively thin layer of electrically conductive material, such as copper, aluminum, gold, silver, or another suitable conductor. Each electrical trace layer 102A-G can also include suitable space between adjacent traces 104, so that the adjacent traces 104 can be electrically insulated from one another. In some examples, the printed circuit board 100 can include between six and twelve electrical trace layers 102A-G, although other suitable numbers of layers can also be used.

A plurality of dielectric layers 106 can electrically insulate the electrical trace layers 102A-G from one another. Each dielectric layer 106 can be positioned between a corresponding pair of adjacent electrical trace layers 102A-G of the plurality of electrical trace layers 102A-G. In some examples, the dielectric layers 106 can be thicker than the electrical trace layers 102A-G. In some examples, the dielectric layers 106 all have a same thickness. In other examples, at least one dielectric layer 106 is thicker than another dielectric layer 106. In some examples, because the electrical trace layers 102A-G can include spaces between adjacent electrical traces 104, a dielectric layer 106 can contact an adjacent dielectric layer 106 in the spaces between adjacent electrical traces 104.

A first electrically conductive via 108 can extend through the plurality of electrical trace layers 102A-G from a top electrical trace layer 102A of the plurality of electrical trace layers 102A-G, to a bottom electrical trace layer 102G of the plurality of electrical trace layers 102A-G. The first electrically conductive via 108 can be formed as a plated through hole (PTH) via. To form a plated through hole via, a hole can be drilled through the printed circuit board 100, and the hole can be filled with an electrically conductive material, such as copper, aluminum, gold, silver, or another suitable conductor. The resulting structure can be a cylinder of electrically conductive material, known as a stub, that extends from a top of the printed circuit board 100 to a bottom of the printed circuit board 100.

The first electrically conductive via 108 can electrically connect to a first electrical trace 110 patterned in a first electrical trace layer 102B of the plurality of electrical trace layers 102A-G. Although FIG. 1 shows the first electrical trace layer 102B as being the second electrical trace layer from the top electrical trace layer, it will be understood that any suitable electrical trace layer in the plurality of electrical trace layers 102A-G can be used to form the first electrical trace layer, including the top or bottom electrical trace layer.

A second electrically conductive via 112 can extend through the plurality of electrical trace layers 102A-G from the top electrical trace layer 102A to the bottom electrical trace layer 102G. In some examples, the first and second electrically conductive vias can be positioned directly adjacent to each other, such that a line segment connecting the first and second electrically conductive vias does not intersect any other electrically conductive vias. In some examples, the second electrically conductive via 112 can be formed in the same manner as the first electrically conductive via 108, and can include a cylinder of electrically conductive material, or stub, that extends from a top of the printed circuit board 100 to a bottom of the printed circuit board 100.

The second electrically conductive via 112 can electrically connect to a second electrical trace 114 patterned in a second electrical trace layer of the plurality of electrical trace layers 102A-G. Although FIG. 1 shows the second electrical trace layer 102C as being the third electrical trace layer from the top electrical trace layer, it will be understood that any suitable electrical trace layer in the plurality of electrical trace layers 102A-G can be used to form the second electrical trace layer, including the top or bottom electrical trace layer. Typically, the second electrical trace layer can be different from the first electrical trace layer.

A via connection trace 116 can be patterned in one of the plurality of electrical trace layers 102A-G. The via connection trace 116 can electrically connect the first electrically conductive via 108 to the second electrically conductive via 112, such that an electrical path extends from the first electrical trace 110, through at least a portion of the first electrically conductive via 108, through at least a portion of the via connection trace 116, through at least a portion of the second electrically conductive via 112, to the second electrical trace 114. Using two vias in this manner (e.g., sending current from one trace down one via and up and adjacent via to another trace, rather than using a single via to connect the traces directly to each other) can shorten the length of unused portions of the stub or stubs (e.g. portions that form an open circuit), and can increase a frequency of electrical resonances in these unused portions to avoid interfering with electrical data signals sent through the first electrical trace 110 and the second electrical trace 114.

In some examples, including the specific configuration shown in FIG. 1, the via connection trace 116 can be patterned in the bottom electrical trace layer 102G. In some of these examples, a separation 118 between the first electrical trace layer 102B and the top electrical trace layer 102A can be less than a separation between the first electrical trace layer 102B and the bottom electrical trace layer 102G. In some of these examples, a separation 120 between the second electrical trace layer 102C and the top electrical trace layer 102A is less than a separation between the second electrical trace layer 102C and the bottom electrical trace layer 102G.

In other examples, the via connection trace 116 can be patterned in the top electrical trace layer 102A. In some of these examples, a separation between the first electrical trace layer 102B and the bottom electrical trace layer 102G can be less than a separation between the first electrical trace layer 102B and the top electrical trace layer 102A. In some of these examples, a separation between the second electrical trace layer 102C and the bottom electrical trace layer 102G can be less than a separation between the second electrical trace layer 102C and the top electrical trace layer 102A.

In some examples, the via connection trace 116 can extend between a first end, positioned at the first electrically conductive via 108, and a second end, positioned at the second electrically conductive via 112. For these examples, the electrical path can extend through a full length of the via connection trace 116. In other examples, the via connection trace 116 can extend beyond the first electrically conductive via 108 and/or beyond the second electrically conductive via 112, so that the electrical path can extend through only a portion of the via connection trace 116.

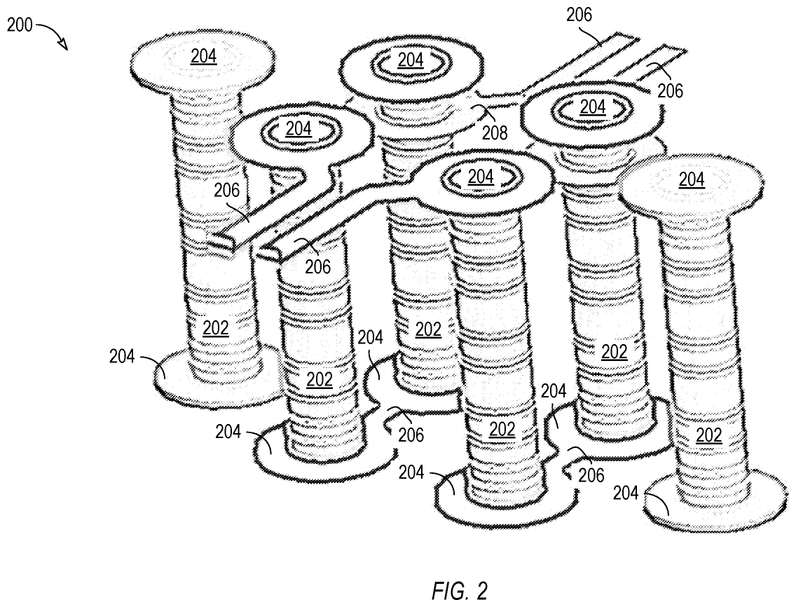

FIG. 2 shows a perspective view of an example of various electrically conductive elements of a printed circuit board (PCB) 200, in accordance with some embodiments. The supporting structure and dielectric layers of the printed circuit board 200 are omitted for clarity. The configuration of FIG. 2 is intended to be cumulative with the configuration of FIG. 1, and includes some additional features not shown in FIG. 1. The printed circuit board of FIG. 2 is but one example of a printed circuit board; other configurations can also be used.

In the configuration of FIG. 2, each via 202 can optionally include an electrically conductive via cap 204 at its top end and/or at its bottom end. The via cap 204 can connect to an electrical trace 206, where appropriate. Electrically connecting a trace 206 to the via cap 204 can be easier than connecting the trace directly to the stub, due to the larger size of the via cap 204. Each via cap 204 can include a disc of electrically conductive material, each disc having a diameter greater than a diameter of the stub. Each via cap 204 can be coaxial with the stub. Each via cap 204 can be formed as an electrically conductive annular ring that surrounds the via stub.

In the configuration of FIG. 2, each via 202 can optionally include an electrically conductive via ring 208 at an electrical trace layer other than the top electrical trace layer or the bottom electrical trace layer. The via ring 208 can connect to an electrical trace 206, where appropriate. For electrical trace layers in which the via 202 does not connect to a trace 206, the via ring 208 can be absent. Electrically connecting a trace 206 to the via ring 208 can be easier than connecting the trace 206 directly to the stub, due to the larger size of the via ring 208. Each via ring 208 can include a disc of electrically conductive material, each disc having a diameter greater than a diameter of the stub. Each via ring 208 can be coaxial with the stub. Each via ring 208 can be formed as an electrically conductive annular ring that circumferentially surrounds the via stub.

In the configuration of FIG. 2, the printed circuit board 200 can include two electrical paths, which can optionally have matching electrical path lengths, and which can be used to electrically conduct a pair of differential signals. In some examples, the two electrical paths can be adjacent to each other, including sections of electrical traces 206 that are parallel to each other and are positioned in the same electrical trace layer. The two electrical paths can follow parallel sets of vias 202 to connect from one set of electrical traces, in a first electrical trace layer, to another set of electrical traces, in a second electrical trace layer.

In the specific configuration of FIG. 2, a first of the pair of differential signals can propagate from a first electrical trace, at a first electrical trace layer that is also the top electrical trace layer, to a via cap at a first via, to the first via, through the first via to a bottom of the first via, to a via cap at the bottom of the first via, through a first via connection trace to a via cap at a bottom of a second via, through a portion of the second via to an second electrical trace layer, to a via cap at the second electrical trace layer, to a second electrical trace at the second electrical trace layer.

Similarly, in the specific configuration of FIG. 2, a second of the pair of differential signals can propagate from a third electrical trace, at the first electrical trace layer that is also the top electrical trace layer, to a via cap at a third via, to the third via, through the third via to a bottom of the third via, to a via cap at the bottom of the third via, through a second via connection trace to a via cap at a bottom of a fourth via, through a portion of the fourth via to the second electrical trace layer, to a via cap at the second electrical trace layer, to a fourth electrical trace at the second electrical trace layer.

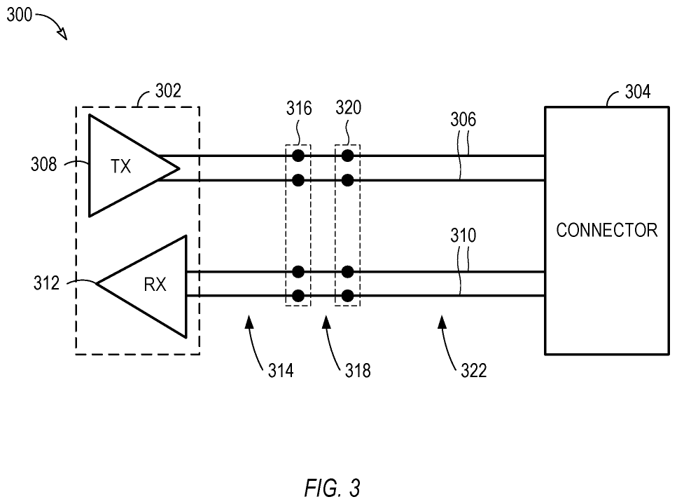

FIG. 3 shows a top-view schematic view of the electrical traces and vias of a printed circuit board, in accordance with some embodiments. The configuration of FIG. 3 is intended to be cumulative with the configuration of FIG. 2, and includes some additional features not shown in FIG. 2. The configuration of FIG. 3 is but one configuration; other suitable configurations can also be used.

In the configuration of FIG. 3, the printed circuit board 300 can electrically connect a transceiver 302 to a connector 304, such as a USB3.1 Gen2 connector. The printed circuit board 300 can include a first differential signal pair 306 connecting a transmitter 308 of the transceiver 302 to the connector 304, and a second differential signal pair 310 connecting a receiver 312 of the transceiver 302 to the connector 304. Although only one set of electrical connections is shown for each of the transmitter 308 and the receiver 312, it will be understood that more than one set of electrical connections can also be used.

In each electrical path of each of the differential signal pairs 306, 310, a first electrical trace 314 can connect the transceiver to a first via 316, the first via 316 can connect to a via connection trace 318, the via connection trace 318 can connect to a second via 320, the second via 320 can connect to a second electrical trace 322, and the second electrical trace 322 can connect to the connector 304. Although each electrical path is shown as including one pair of vias, it will be understood that additional pairs of vias can optionally be used to route the electrical path as needed through components (not shown), which can be positioned on different electrical trace layers. The via caps and via rings are not shown in FIG. 3.

In addition to connecting a transceiver to a connector, the printed circuit board can alternatively be configured to connect a transceiver to another transceiver, a transceiver to a passive component, a connector to a passive component, or another suitable configuration.

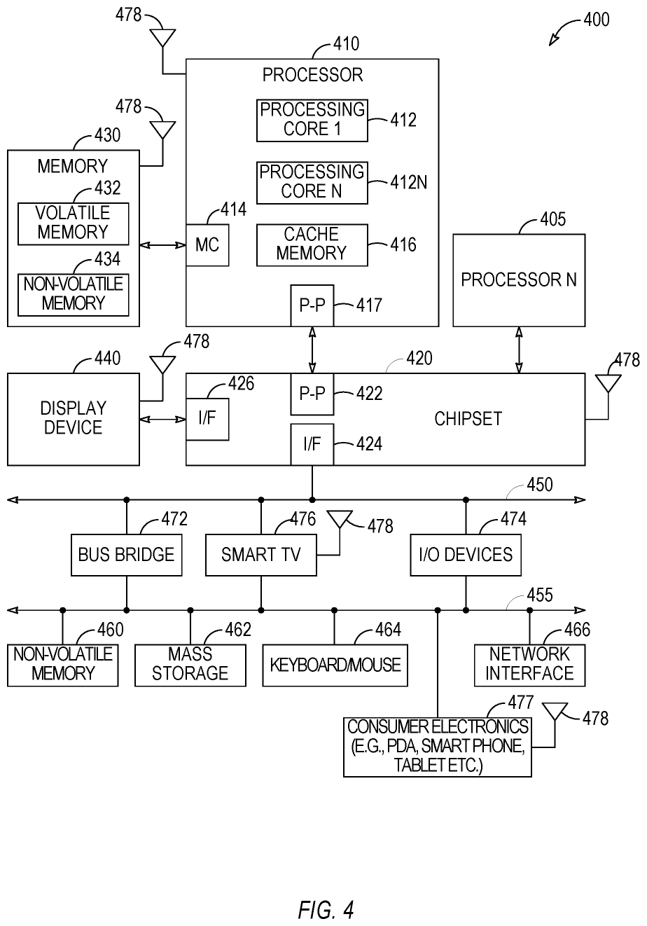

FIG. 4 illustrates a system level diagram, depicting an example of an electronic device (e.g., system) including the printed circuit board as described in the present disclosure. FIG. 4 is included to show an example of a higher-level device application for the printed circuit board. In one embodiment, system 400 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 400 is a system on a chip (SOC) system.

In one embodiment, processor 410 has one or more processor cores 412 and 412N, where 412N represents the Nth processor core inside processor 410 where N is a positive integer. In one embodiment, system 400 includes multiple processors including 410 and 405, where processor 405 has logic similar or identical to the logic of processor 410. In some embodiments, processing core 412 includes, but is not limited to, pre-fetch logic to fetch instructions, decode logic to decode the instructions, execution logic to execute instructions and the like. In some embodiments, processor 410 has a cache memory 416 to cache instructions and/or data for system 400. Cache memory 416 may be organized into a hierarchal structure including one or more levels of cache memory.

In some embodiments, processor 410 includes a memory controller 414, which is operable to perform functions that enable the processor 410 to access and communicate with memory 430 that includes a volatile memory 432 and/or a non-volatile memory 434. In some embodiments, processor 410 is coupled with memory 430 and chipset 420. Processor 410 may also be coupled to a wireless antenna 478 to communicate with any device configured to transmit and/or receive wireless signals. In one embodiment, an interface for wireless antenna 478 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 432 includes, but is not limited to, Synchronous Dynamic Random-Access Memory (SDRAM), Dynamic Random-Access Memory (DRAM), RAMBUS Dynamic Random-Access Memory (RDRAM), and/or any other type of random access memory device. Non-volatile memory 434 includes, but is not limited to, flash memory, phase change memory (PCM), read-only memory (ROM), electrically erasable programmable read-only memory (EEPROM), or any other type of non-volatile memory device.

Memory 430 stores information and instructions to be executed by processor 410. In one embodiment, memory 430 may also store temporary variables or other intermediate information while processor 410 is executing instructions. In the illustrated embodiment, chipset 420 connects with processor 410 via Point-to-Point (PtP or P-P) interfaces 417 and 422. Chipset 420 enables processor 410 to connect to other elements in system 400. In some embodiments of the example system, interfaces 417 and 422 operate in accordance with a PtP communication protocol such as the Intel® QuickPath Interconnect (QPI) or the like. In other embodiments, a different interconnect may be used.

In some embodiments, chipset 420 is operable to communicate with processor 410, 405N, display device 440, and other devices, including a bus bridge 472, a smart TV 476, I/O devices 474, nonvolatile memory 460, a storage medium (such as one or more mass storage devices) 462, a keyboard/mouse 464, a network interface 466, and various forms of consumer electronics 477 (such as a PDA, smart phone, tablet etc.), etc. In one embodiment, chipset 420 couples with these devices through an interface 424. Chipset 420 may also be coupled to a wireless antenna 478 to communicate with any device configured to transmit and/or receive wireless signals.

Chip set 420 connects to display device 440 via interface 426. Display 440 may be, for example, a liquid crystal display (LCD), a light emitting diode (LED) array, an organic light emitting diode (OLED) array, or any other form of visual display device. In some embodiments of the example system, processor 410 and chipset 420 are merged into a single SOC. In addition, chipset 420 connects to one or more buses 450 and 455 that interconnect various system elements, such as I/O devices 474, nonvolatile memory 460, storage medium 462, a keyboard/mouse 464, and network interface 466. Buses 450 and 455 may be interconnected together via a bus bridge 472.

In one embodiment, mass storage device 462 includes, but is not limited to, a solid-state drive, a hard disk drive, a universal serial bus flash memory drive, or any other form of computer data storage medium. In one embodiment, network interface 466 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 4 are depicted as separate blocks within the system 400, the functions performed by some of these blocks may be integrated within a single semiconductor circuit or may be implemented using two or more separate integrated circuits. For example, although cache memory 416 is depicted as a separate block within processor 410, cache memory 416 (or selected aspects of 416) can be incorporated into processor core 412.

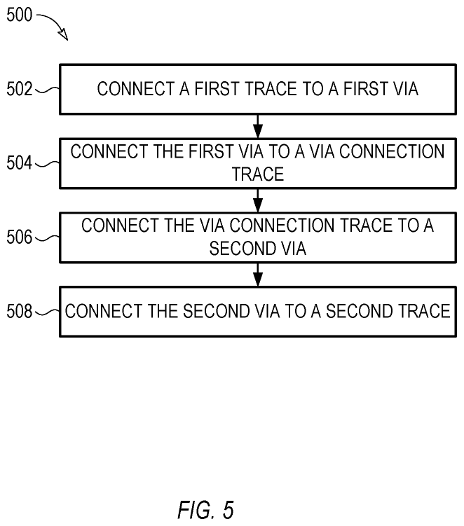

FIG. 5 shows a flowchart of an example of a method 500 for forming an electrical connection in a printed circuit board, in accordance with some embodiments. The method 500 can be executed on the printed circuit boards of FIGS. 1-3, in addition to other printed circuit boards. The method 500 is but one example of a method for forming an electrical connection in a printed circuit board; other suitable methods can also be used.

At operation 502, a first electrical trace, patterned in a first electrical trace layer of a plurality of electrical trace layers in a multilayer printed circuit board, can be electrically connected to a first electrically conductive via extending through the multilayer printed circuit board from a top electrical trace layer of the plurality of electrical trace layers to a bottom electrical trace layer of the plurality of electrical trace layers.

At operation 504, the first electrically conductive via can be electrically connected to a via connection trace patterned in one of the plurality of electrical trace layers.

At operation 506, the via connection trace can be electrically connected to a second electrically conductive via extending through the multilayer printed circuit board from the top electrical trace layer to the bottom electrical trace layer.

At operation 508, the second electrically conductive via can be electrically connected to a second electrical trace, patterned in a second electrical trace layer of the plurality of electrical trace layers.

In some examples, the via connection trace can be patterned in one of the top electrical trace layer or the bottom electrical trace layer.

In some examples, the first and second electrically conductive vias can be positioned directly adjacent to each other, such that a line segment connecting the first and second electrically conductive vias does not intersect any other electrically conductive vias.

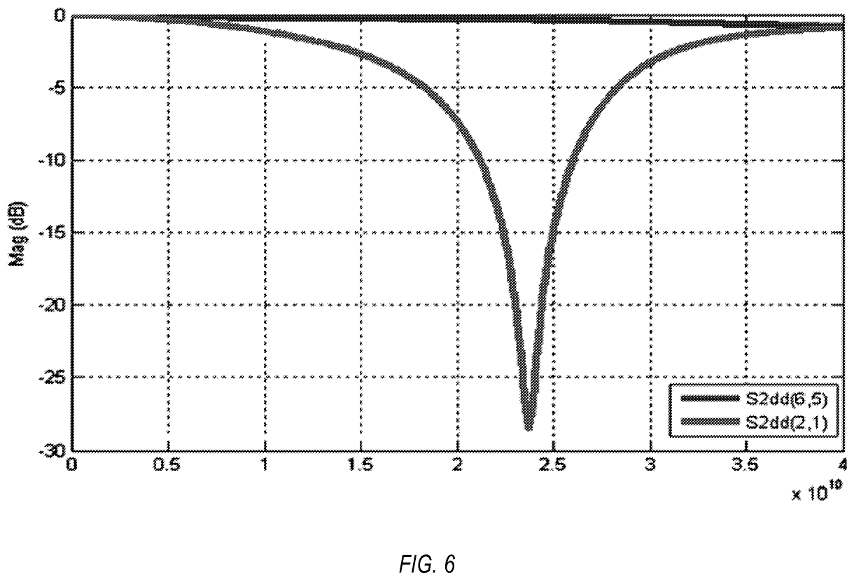

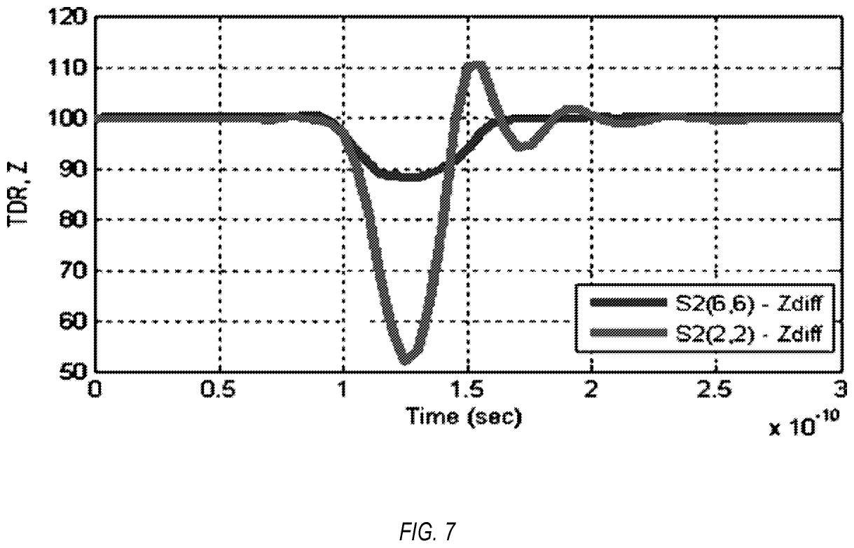

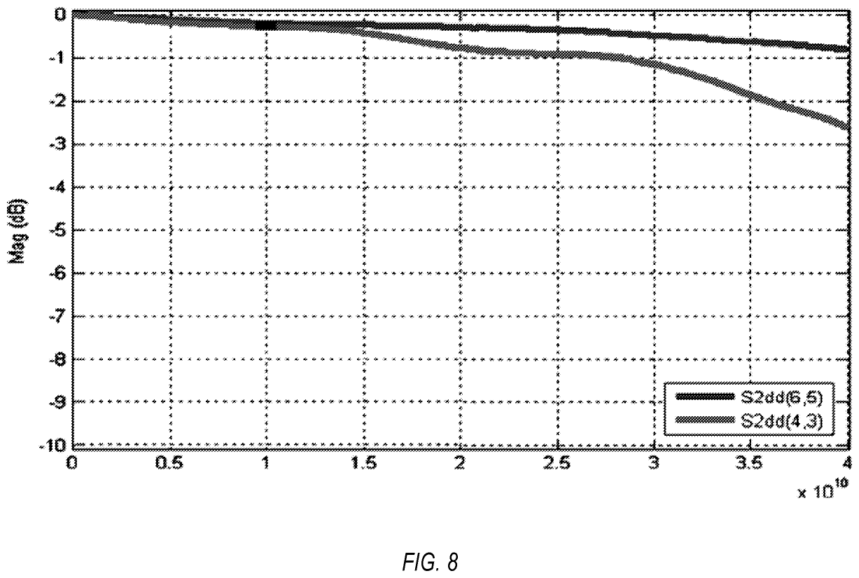

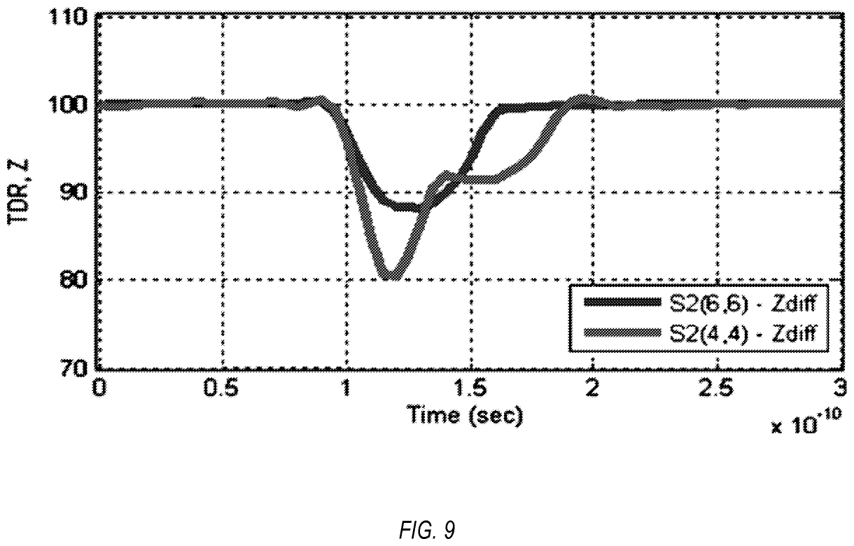

FIGS. 6-9 show plots of simulated performance for the electrical architecture discussed above. FIGS. 6 and 7 show simulated performance of stub geometry that represents the problem discussed herein. FIGS. 8 and 9 show simulated performance of the two-via geometry that represents a solution to the problem discussed herein.

FIG. 6 shows a plot of simulated insertion loss as a function of frequency, for plated through hole vias that lack a stub and include a stub.

A first plot (upper curve) shows simulated performance for a via lacking a stub. The first plot descends monotonically from 0 dB at 0 Hz to a relatively small insertion loss, around −1 dB, at a frequency of 40 GHz.

A second plot (lower curve) shows simulated performance for a via that has a relatively long stub, due to signals exiting on a third layer. The second plot descends relatively quickly from 0 dB at 0 Hz to a relatively large insertion loss, peaking at around −27 dB at a frequency of about 24 GHz, and ascends to around −1 dB at a frequency of 40 GHz. For data rates between about 18 GHz and about 28 GHz, the stub would produce an insertion loss of greater than −5 dB, which would severely hamper data transmission in this frequency range.

FIG. 7 shows a plot of simulated time domain reflection, as a function of time, for plated through hole vias that lack a stub and include a stub.

A first plot (upper curve) shows simulated performance for a via lacking a stub. The first plot remains at 100 arbitrary units from 0 sec to about 0.07 nanoseconds, drops to about 89 arbitrary units at about 0.12 nanoseconds, rises to 100 arbitrary units at about 0.17 nanoseconds, and remains at 100 arbitrary units at above 0.17 nanoseconds.

A second plot (lower curve) shows simulated performance for a via that has a relatively long stub, due to signals exiting on a third layer. The second plot remains at 100 arbitrary units from 0 sec to about 0.07 nanoseconds, drops to about 52 arbitrary units at about 0.12 nanoseconds, rises to about 110 arbitrary units at about 0.15 nanoseconds, and shows significant ringing that diminishes over time to settle at at 100 arbitrary units at above 0.3 nanoseconds. Such ringing is consistent with a resonant behavior, caused by reflections between top and bottom ends of the unused (e.g., open-ended circuit) portions of the stub.

From FIGS. 6 and 7, one can conclude that the unused (e.g., open-ended circuit) portions of the stub create relatively severe problems for data rates around 24 GHz. The numerical value of this problem area can scale with the length of the unused portion of the stub. The shorter the unused portion of the stub, the higher the data rate at which the geometry causes severe insertion loss.

FIG. 8 shows a plot of simulated insertion loss as a function of frequency, for plated through hole vias that lack a stub and include the two-via geometry discussed above.

A first plot (upper curve) corresponds to the first plot (upper curve) shown in FIG. 6. The first plot shows simulated performance for a via lacking a stub. The first plot descends from 0 dB at 0 Hz to a relatively small insertion loss, around −1 dB, at a frequency of 40 GHz. This first plot corresponds to the first plot (upper curve) shown in FIG. 6.

A second plot (lower curve) shows simulated performance for a two-via geometry discussed above. The second plot descends monotonically from 0 dB at 0 Hz to a relatively small insertion loss, around −3 dB, at a frequency of 40 GHz. For data rates between about 18 GHz and about 28 GHz, the insertion loss is less than or equal to −1 dB. This plot shows significantly improved performance over the long-stub second plot (lower curve) of FIG. 6, which shows insertion loss of over −5 dB for this frequency range.

FIG. 9 shows a plot of simulated time domain reflection, as a function of time, for plated through hole vias that lack a stub and include the two-via geometry discussed above.

A first plot (upper curve) corresponds to the first plot (upper curve) shown in FIG. 7. The first plot remains at 100 arbitrary units from 0 sec to about 0.07 nanoseconds, drops to about 89 arbitrary units at about 0.12 nanoseconds, rises to 100 arbitrary units at about 0.17 nanoseconds, and remains at 100 arbitrary units at above 0.17 nanoseconds.

A second plot (lower curve) shows simulated performance for the two-via geometry discussed above. The second plot remains at 100 arbitrary units from 0 sec to about 0.07 nanoseconds, drops to about 80 arbitrary units at about 0.12 nanoseconds, rises to about 92 arbitrary units at about 0.14 nanoseconds, then rises to about 100 arbitrary units and about 0.19 nanoseconds, and shows very little ringing above 0.2 nanoseconds. Compared to the corresponding lower curve in FIG. 7, the lower curve of FIG. 9 shows significantly reduced ringing, which is consistent with a reduction in resonant behavior.

From FIGS. 8 and 9, one can conclude that the two-via geometry discussed herein can significantly reduce the undesirable effects of the unused portion of the stub, as discussed above.

Finally, it is beneficial to consider simulated eye pattern data that shows the robustness of the two-via geometry discussed above. For a simulated USB3.1 Gen 2 connector, simulations were run for three cases.

A first case is a Type-3 regular plated through-hole via that assumes a sub length of approximately 26 milli-inches, which represents the geometry of the problem being addressed herein. For this case, the simulated eye height is 9.5 millivolts and the simulated eye width is 6.8 picoseconds.

A second case is a Type-4 microvia, with a stub length of 9 milli-inches, which represents a technically effective, but significantly more expensive, solution to the problem being addressed herein. This case can be considered a “gold standard” for performance. For this case, the simulated eye height is 12.9 millivolts and the simulated eye width is 9.5 picoseconds.

A third case is the two-via geometry discussed above, which represents a technically effective, but relatively inexpensive, solution to the problem being addressed herein. For this case, the simulated eye height is 12.8 millivolts and the simulated eye width is 9.5 picoseconds. The performance of the two-via geometry discussed above nearly matches the performance of the “gold standard” case, and does so with significantly less expense than the “gold standard” process.

For the reasons shown in the simulated plots of FIGS. 6-9, and the simulated eye pattern data, the two-via structure discussed herein can show similar margins (e.g., a negligible margin difference) to a design with a microvia of minimal stub length and a design that uses plated through-hole vias but restricts routing to limit the stub length.

In the foregoing detailed description, the method and apparatus of the present disclosure have been described with reference to specific embodiments thereof. It will, however, be evident that various modifications and changes may be made thereto without departing from the broader spirit and scope of the present disclosure. The present specification and figures are accordingly to be regarded as illustrative rather than restrictive.

To further illustrate the device and related method disclosed herein, a non-limiting list of examples is provided below. Each of the following non-limiting examples can stand on its own, or can be combined in any permutation or combination with any one or more of the other examples.

In Example 1, a printed circuit board can include: a plurality of electrical trace layers extending parallel to one another and electrically insulated from one another; a first electrically conductive via extending through the plurality of electrical trace layers from a top electrical trace layer of the plurality of electrical trace layers, to a bottom electrical trace layer of the plurality of electrical trace layers, the first electrically conductive via electrically connecting to a first electrical trace patterned in a first electrical trace layer of the plurality of electrical trace layers; a second electrically conductive via extending through the plurality of electrical trace layers from the top electrical trace layer to the bottom electrical trace layer, the second electrically conductive via electrically connecting to a second electrical trace patterned in a second electrical trace layer of the plurality of electrical trace layers; and a via connection trace patterned in one of the plurality of electrical trace layers and electrically connecting the first electrically conductive via to the second electrically conductive via, such that an electrical path extends from the first electrical trace, through at least a portion of the first electrically conductive via, through at least a portion of the via connection trace, through at least a portion of the second electrically conductive via, to the second electrical trace.

In Example 2, the printed circuit board of Example 1 can optionally be configured such that the via connection trace is patterned in the top electrical trace layer.

In Example 3, the printed circuit board of any one of Examples 1-2 can optionally be configured such that a separation between the first electrical trace layer and the bottom electrical trace layer is less than a separation between the first electrical trace layer and the top electrical trace layer.

In Example 4, the printed circuit board of any one of Examples 1-3 can optionally be configured such that a separation between the second electrical trace layer and the bottom electrical trace layer is less than a separation between the second electrical trace layer and the top electrical trace layer.

In Example 5, the printed circuit board of any one of Examples 1-4 can optionally be configured such that the via connection trace is patterned in the bottom electrical trace layer.

In Example 6, the printed circuit board of any one of Examples 1-5 can optionally be configured such that a separation between the first electrical trace layer and the top electrical trace layer is less than a separation between the first electrical trace layer and the bottom electrical trace layer.

In Example 7, the printed circuit board of any one of Examples 1-6 can optionally be configured such that a separation between the second electrical trace layer and the top electrical trace layer is less than a separation between the second electrical trace layer and the bottom electrical trace layer.

In Example 8, the printed circuit board of any one of Examples 1-7 can optionally be configured such that the via connection trace extends between a first end, positioned at the first electrically conductive via, and a second end, positioned at the second electrically conductive via; and the electrical path extends through a full length of the via connection trace.

In Example 9, the printed circuit board of any one of Examples 1-8 can optionally be configured such that the first and second electrically conductive vias are directly adjacent to each other, such that a line segment connecting the first and second electrically conductive vias does not intersect any other electrically conductive vias.

In Example 10, the printed circuit board of any one of Examples 1-9 can optionally be configured such that the first electrical trace electrically connects to a connector and the second electrical trace electrically connects to a transceiver.

In Example 11, the printed circuit board of any one of Examples 1-10 can optionally be configured such that the first and second electrical traces form at least a portion of a first of a pair of differential signal paths extending from the transceiver to the connector.

In Example 12, the printed circuit board of any one of Examples 1-11 can optionally be configured such that the printed circuit board further comprises a second of the pair of differential signal paths extending from the transceiver to the connector; and the pair of differential signal paths have a same electrical path length.

In Example 13, the printed circuit board of any one of Examples 1-12 can optionally further include a plurality of dielectric layers, each dielectric layer being positioned between a corresponding pair of adjacent electrical trace layers of the plurality of electrical trace layers.

In Example 14, the printed circuit board of any one of Examples 1-13 can optionally further include a first via ring formed from an electrically conductive material and circumferentially surrounding the first electrically conductive via at the first electrical trace layer, the first via ring electrically connecting the first electrical trace to the first via; and a second via ring formed from an electrically conductive material and circumferentially surrounding the second electrically conductive via at the second electrical trace layer, the second via ring electrically connecting the second electrical trace to the second via.

In Example 15, a method can include: electrically connecting a first electrical trace, patterned in a first electrical trace layer of a plurality of electrical trace layers in a multilayer printed circuit board, to a first electrically conductive via extending through the multilayer printed circuit board from a top electrical trace layer of the plurality of electrical trace layers to a bottom electrical trace layer of the plurality of electrical trace layers; electrically connecting the first electrically conductive via to a via connection trace patterned in one of the plurality of electrical trace layers; electrically connecting the via connection trace to a second electrically conductive via extending through the multilayer printed circuit board from the top electrical trace layer to the bottom electrical trace layer; and electrically connecting the second electrically conductive via to a second electrical trace, patterned in a second electrical trace layer of the plurality of electrical trace layers.

In Example 16, the method of Example 15 can optionally be configured such that the via connection trace is patterned in one of the top electrical trace layer or the bottom electrical trace layer.

In Example 17, the method of any one of Examples 15-16 can optionally be configured such that the first and second electrically conductive vias are directly adjacent to each other, such that a line segment connecting the first and second electrically conductive vias does not intersect any other electrically conductive vias.

In Example 18, a printed circuit board can include: a plurality of electrical trace layers extending parallel to one another and electrically insulated from one another; a first electrically conductive via extending through the plurality of electrical trace layers from a top electrical trace layer of the plurality of electrical trace layers, to a bottom electrical trace layer of the plurality of electrical trace layers, the first electrically conductive via electrically connecting to a first electrical trace patterned in a first electrical trace layer of the plurality of electrical trace layers; a second electrically conductive via extending through the plurality of electrical trace layers from the top electrical trace layer to the bottom electrical trace layer, the second electrically conductive via electrically connecting to a second electrical trace patterned in a second electrical trace layer of the plurality of electrical trace layers; and a via connection trace patterned in one of a top electrical trace layer of the plurality of electrical trace layers or a bottom electrical trace layer of the plurality of electrical trace layers, the via connection trace electrically connecting the first electrically conductive via to the second electrically conductive via, such that an electrical path extends from the first electrical trace, through at least a portion of the first electrically conductive via, through the via connection trace, through at least a portion of the second electrically conductive via, to the second electrical trace.

In Example 19, the printed circuit board of Example 18 can optionally be configured such that the first and second electrically conductive vias are directly adjacent to each other, such that a line segment connecting the first and second electrically conductive vias does not intersect any other electrically conductive vias.

In Example 20, the printed circuit board of any one of Examples 18-19 can optionally be configured such that the first electrical trace electrically connects to a transceiver and the second electrical trace electrically connects to a connector; the first and second electrical traces form at least a portion of a first of a pair of differential signal paths extending from the transceiver to the connector; the printed circuit board further comprises a second of the pair of differential signal paths extending from the transceiver to the connector; and the pair of differential signal paths have a same electrical path length.

What is claimed is:

1. A printed circuit board, comprising:
a plurality of electrical trace layers extending parallel to one another and electrically insulated from one another;
a first electrically conductive via extending through the plurality of electrical trace layers from a top electrical trace layer of the plurality of electrical trace layers, to a bottom electrical trace layer of the plurality of electrical trace layers, the first electrically conductive via electrically connecting to a first electrical trace patterned in a first electrical trace layer of the plurality of electrical trace layers;
a second electrically conductive via extending through the plurality of electrical trace layers from the top electrical trace layer to the bottom electrical trace layer, the second electrically conductive via electrically connecting to a second electrical trace patterned in a second electrical trace layer of the plurality of electrical trace layers; and
a via connection trace patterned in one of the plurality of electrical trace layers and electrically connecting the first electrically conductive via to the second electrically conductive via, such that an electrical path extends from the first electrical trace, through at least a portion of the first electrically conductive via, through at least a portion of the via connection trace, through at least a portion of the second electrically conductive via, to the second electrical trace.

2. The printed circuit board of claim 1, wherein the via connection trace is patterned in the top electrical trace layer.

3. The printed circuit board of claim 2, wherein a separation between the first electrical trace layer and the bottom electrical trace layer is less than a separation between the first electrical trace layer and the top electrical trace layer.

4. The printed circuit board of claim 2, wherein a separation between the second electrical trace layer and the bottom electrical trace layer is less than a separation between the second electrical trace layer and the top electrical trace layer.

5. The printed circuit board of claim 1, wherein the via connection trace is patterned in the bottom electrical trace layer.

6. The printed circuit board of claim 5, wherein a separation between the first electrical trace layer and the top electrical trace layer is less than a separation between the first electrical trace layer and the bottom electrical trace layer.

7. The printed circuit board of claim 5, wherein a separation between the second electrical trace layer and the top electrical trace layer is less than a separation between the second electrical trace layer and the bottom electrical trace layer.

8. The printed circuit board of claim 1, wherein:
the via connection trace extends between a first end, positioned at the first electrically conductive via, and a second end, positioned at the second electrically conductive via; and
the electrical path extends through a full length of the via connection trace.

9. The printed circuit board of claim 1, wherein the first and second electrically conductive vias are directly adjacent to each other, such that a line segment connecting the first and second electrically conductive vias does not intersect any other electrically conductive vias.

10. The printed circuit board of claim 1, wherein the first electrical trace electrically connects to a connector and the second electrical trace electrically connects to a transceiver.

11. The printed circuit board of claim 10, wherein the first and second electrical traces form at least a portion of a first of a pair of differential signal paths extending from the transceiver to the connector.

12. The printed circuit board of claim 11, wherein:
the printed circuit board further comprises a second of the pair of differential signal paths extending from the transceiver to the connector; and
the pair of differential signal paths have a same electrical path length.

13. The printed circuit board of claim 1, further comprising:
a plurality of dielectric layers, each dielectric layer being positioned between a corresponding pair of adjacent electrical trace layers of the plurality of electrical trace layers.

14. The printed circuit board of claim 1, further comprising:
a first via ring formed from an electrically conductive material and circumferentially surrounding the first electrically conductive via at the first electrical trace layer, the first via ring electrically connecting the first electrical trace to the first via; and
a second via ring formed from an electrically conductive material and circumferentially surrounding the second electrically conductive via at the second electrical trace layer, the second via ring electrically connecting the second electrical trace to the second via.

15. A method, comprising:
electrically connecting a first electrical trace, patterned in a first electrical trace layer of a plurality of electrical trace layers in a multilayer printed circuit board, to a first electrically conductive via extending through the multilayer printed circuit board from a top electrical trace layer of the plurality of electrical trace layers to a bottom electrical trace layer of the plurality of electrical trace layers;
electrically connecting the first electrically conductive via to a via connection trace patterned in one of the plurality of electrical trace layers;
electrically connecting the via connection trace to a second electrically conductive via extending through the multilayer printed circuit board from the top electrical trace layer to the bottom electrical trace layer; and
electrically connecting the second electrically conductive via to a second electrical trace, patterned in a second electrical trace layer of the plurality of electrical trace layers.

16. The method of claim 15, wherein the via connection trace is patterned in one of the top electrical trace layer or the bottom electrical trace layer.

17. The method of claim 15, wherein the first and second electrically conductive vias are directly adjacent to each other, such that a line segment connecting the first and second electrically conductive vias does not intersect any other electrically conductive vias.

18. A printed circuit board, comprising:
a plurality of electrical trace layers extending parallel to one another and electrically insulated from one another;
a first electrically conductive via extending through the plurality of electrical trace layers from a top electrical trace layer of the plurality of electrical trace layers, to a bottom electrical trace layer of the plurality of electrical trace layers, the first electrically conductive via electrically connecting to a first electrical trace patterned in a first electrical trace layer of the plurality of electrical trace layers;
a second electrically conductive via extending through the plurality of electrical trace layers from the top electrical trace layer to the bottom electrical trace layer, the second electrically conductive via electrically connecting to a second electrical trace patterned in a second electrical trace layer of the plurality of electrical trace layers; and
a via connection trace patterned in one of a top electrical trace layer of the plurality of electrical trace layers or a bottom electrical trace layer of the plurality of electrical trace layers, the via connection trace electrically connecting the first electrically conductive via to the second electrically conductive via, such that an electrical path extends from the first electrical trace, through at least a portion of the first electrically conductive via, through the via connection trace, through at least a portion of the second electrically conductive via, to the second electrical trace.

19. The printed circuit board of claim 18, wherein the first and second electrically conductive vias are directly adjacent to each other, such that a line segment connecting the first and second electrically conductive vias does not intersect any other electrically conductive vias.

20. The printed circuit board of claim 19, wherein:
the first electrical trace electrically connects to a transceiver and the second electrical trace electrically connects to a connector;
the first and second electrical traces form at least a portion of a first of a pair of differential signal paths extending from the transceiver to the connector;
the printed circuit board further comprises a second of the pair of differential signal paths extending from the transceiver to the connector; and
the pair of differential signal paths have a same electrical path length.
